(19) United States
(12) Patent Application Publication
(10) Pub. No.: US 2024/0243031 A1
(43) Pub. Date: Jul. 18, 2024

(54) Thermal Enhanced Power Semiconductor Package

(71) Applicant: Wolfspeed, Inc., Durham, NC (US)

(72) Inventors: Yusheng Lin, Phoenix, AZ (US); Kuldeep Saxena, Sewickley, PA (US); Devarajan Balaraman, Apex, NC (US)

(21) Appl. No.: 18/154,353

(22) Filed: Jan. 13, 2023

(51) Int. Cl. H01L 23/373; H01L 23/538; H01L 25/07; H01L 29/16; H01L 29/872

(52) U.S. Cl. CPC H01L 23/3735; H01L 23/5389; H01L 25/072; H01L 29/1608; H01L 29/872

(57) ABSTRACT

Power semiconductor packages are provided. In one example, a power semiconductor package may include a first carrier substrate. The first carrier substrate may include one or more conductive pads. The power semiconductor package may include a second carrier substrate. The second carrier substrate may include one or more conductive leads. The power semiconductor package may include a power semiconductor die having a first surface and an opposing second surface. The first surface of the power semiconductor die may be directly coupled to the first carrier substrate. The second surface of the power semiconductor die may be directly coupled to the second carrier substrate.

### FIELD

The present disclosure relates generally to semiconductor packages.

### BACKGROUND

Semiconductor devices such as transistors and diodes are ubiquitous in modern electronic devices. Wide band gap semiconductor material systems such as gallium arsenide (GaAs), gallium nitride (GaN), and silicon carbide (SiC) are being increasingly utilized in semiconductor devices to push the boundaries of device performance in areas such as switching speed, power handling capability, and thermal conductivity. Example power semiconductor devices may include metal-oxide-semiconductor field-effect transistors (MOSFETs), insulated gate bipolar transistors (IGBTs), Schottky barrier diodes, PiN diodes, thyristors, and high electron mobility transistors (HEMTs). Packaging technology may play a large role in the performance of power semiconductor devices.

### SUMMARY

Aspects and advantages of embodiments of the present disclosure will be set forth in part in the following description, or may be learned from the description, or may be learned through practice of the embodiments.

One example aspect of the present disclosure is directed to a power semiconductor package. The power semiconductor package may include a first carrier substrate. The first carrier substrate may include one or more conductive pads. The power semiconductor package may include a second carrier substrate. The second carrier substrate may include one or more conductive leads. The power semiconductor package may include a power semiconductor die having a first surface and an opposing second surface. The first surface of the power semiconductor die may be directly coupled to the first carrier substrate. The second surface of the power semiconductor die may be directly coupled to the second carrier substrate.

Another example aspect of the present disclosure is directed to a power semiconductor package. The power semiconductor package may include a first carrier substrate. The power semiconductor package may include a second carrier substrate. The power semiconductor package may include a power semiconductor die having a first surface and an opposing second surface. The power semiconductor die may include a source contact and a gate contact on the first surface. The power semiconductor die may include a drain contact on the second surface. The first surface of the power semiconductor die may be directly coupled to the first carrier substrate in a flip chip configuration such that the source contact and the gate contact are directly coupled to the first carrier substrate. The second surface of the power semiconductor die may be directly coupled to the second carrier substrate.

Another example aspect of the present disclosure is directed to a power semiconductor package. The power semiconductor package may include a first carrier substrate. The power semiconductor package may include a second carrier substrate. The power semiconductor package may include a power semiconductor die having a first surface and an opposing second surface. The power semiconductor die may include a source contact and a gate contact on the first surface. The power semiconductor die may include a drain contact on the second surface. The power semiconductor package may include an insulating layer on the first surface of the semiconductor die. The power semiconductor package may include an encapsulating portion. The first surface of the power semiconductor die may be directly coupled to the first carrier substrate. The second surface of the power semiconductor die may be directly coupled to the second carrier substrate.

Another example aspect of the present disclosure is directed to a method of fabricating a power semiconductor package. The method may include directly coupling a power semiconductor die to a first carrier substrate to form a first assembly. The method may include directly coupling the first assembly to a second carrier substrate. The second carrier substrate may include one or more conductive leads. The method may include encapsulating at least a portion of the first carrier substrate, the second carrier substrate, and the power semiconductor die to form an encapsulating portion.

These and other features, aspects and advantages of various embodiments will become better understood with reference to the following description and appended claims. The accompanying drawings, which are incorporated in and constitute a part of this specification, illustrate embodiments of the present disclosure and, together with the description, explain the related principles.

### BRIEF DESCRIPTION OF THE DRAWINGS

Detailed discussion of embodiments directed to one of ordinary skill in the art are set forth in the specification, which refers to the appended figures, in which:

FIG. 1 depicts a power semiconductor package according to example embodiments of the present disclosure.

FIG. 2 depicts a flow chart of an example method according to example embodiments of the present disclosure.

FIG. 3 depicts example direct coupling of a power semiconductor die to a first carrier substrate to form a first assembly according to example embodiments of the present disclosure.

FIG. 4 depicts an example first carrier substrate according to example embodiments of the present disclosure.

FIG. 5 depicts an example semiconductor die directly coupled to a first carrier substrate in a flip chip configuration according to example embodiments of the present disclosure.

FIG. 6 depicts forming of an example insulating layer on the power semiconductor die according to example embodiments of the present disclosure.

FIG. 7 depicts example singulation of the first assembly(s) according to example embodiments of the present disclosure.

FIG. 8 depicts an example first assembly according to example embodiments of the present disclosure.

FIG. 9 depicts example direct coupling of a first assembly to a second carrier substrate according to example embodiments of the present disclosure.

FIG. 10 depicts example encapsulating of at least a portion of the first carrier substrate, second carrier substrate, and power semiconductor die to form an encapsulating portion of a power semiconductor package according to example embodiments of the present disclosure.

FIG. 11 depicts a power semiconductor package according to example embodiments of the present disclosure.

FIG. 12 depicts a power semiconductor package according to example embodiments of the present disclosure.

FIG. 13 depicts a power semiconductor package according to example embodiments of the present disclosure.

FIG. 14 depicts a power semiconductor package according to example embodiments of the present disclosure.

### DETAILED DESCRIPTION

Reference now will be made in detail to embodiments, one or more examples of which are illustrated in the drawings. Each example is provided by way of explanation of the embodiments, not limitation of the present disclosure. In fact, it will be apparent to those skilled in the art that various modifications and variations may be made to the embodiments without departing from the scope or spirit of the present disclosure. For instance, features illustrated or described as part of one embodiment may be used with another embodiment to yield a still further embodiment. Thus, it is intended that aspects of the present disclosure cover such modifications and variations.

Discrete semiconductor packages have been developed that include a semiconductor die, such as a MOSFET or a Schottky diode. Such semiconductor packages with MOSFETs may be employed in a variety of applications to enable higher switching frequencies along with reduced associated losses, higher blocking voltages, and improved avalanche capabilities. Example applications may include high performance industrial power supplies, server/telecom power, electric vehicle charging systems, energy storage systems, uninterruptible power supplies, high-voltage DC/DC converters, electric vehicles, and battery management systems. Discrete semiconductor packages with Schottky diodes may be employed in many of the same high-performance power applications described above for MOSFETs, sometimes in systems that also include discrete power packages of MOSFETs.

Packaging technology for semiconductor devices plays an important role in defining the performance of the semiconductor devices. For example, the packaging of a power semiconductor die may limit the ability of the semiconductor die to dissipate heat, conduct current, or even switch at particular speeds (e.g., due to stray inductance). Ineffective heat dissipation can create problems for semiconductor devices (e.g., small form factor semiconductor devices) or in situations where the semiconductor device comes into close contact with the housing. Excessive heat can adversely impact the operation of the semiconductor device itself, as well as the electronic system that uses that semiconductor device.

Moreover, discrete semiconductor packages may use wire bond(s) (e.g., aluminum wire bond(s)) for interconnection between portions of the semiconductor die (e.g., a gate of semiconductor device) and the package (e.g., a lead frame). The use of wire bond(s) may limit the power and the ampacity accommodated by the package. Many solutions to increase power and ampacity handling capabilities of a power semiconductor package focus on high thermal conductivity materials to enhance thermal dissipation and use of a conductive clip or ribbon to make interconnections to increase ampacity. In these examples, interconnection(s) between the gate of the semiconductor device and the lead frame may still be by wire bond, which may serve as one of the weakest points in the discrete semiconductor package.

Example aspects of the present disclosure are directed to power semiconductor packages that may provide for a second thermal dissipation path for the power semiconductor die. In addition, in some examples, the power semiconductor packages do not include any wire bonds to the power semiconductor die.

More particularly, in example embodiments, a power semiconductor package may include a first carrier substrate, such as a direct bonded copper (DBC) substrate or an active metal brazed (AMB) substrate. The first carrier substrate may include one or more conductive pads. A power semiconductor die may be directly coupled to the first carrier substrate. As used herein, the power semiconductor die is directly coupled to the first carrier substrate when the power semiconductor die is attached to the first carrier substrate (e.g., with or without an attach material such as solder, paste, sintered material, etc.) without any intervening structures, such as wire bonds, wire ribbons, clips, or other structures.

In some examples, the power semiconductor die is directly coupled to the first carrier substrate in a flip chip configuration. In a flip chip configuration, the semiconductor die is “flipped” so that contacts associated with a typical outward facing surface of the semiconductor die (e.g., a source contact, a kelvin contact, a gate contact, etc.) are directly coupled to the first carrier substrate (e.g., using an attach material).

The power semiconductor die may be based on a wide band gap semiconductor material. A wide band gap semiconductor has a band gap greater than about 1.40 eV, such as silicon carbide and/or a Group III-nitride (e.g., gallium nitride). In some examples, the power semiconductor die may include semiconductor devices, such as transistors, diodes, and/or thyristors. For instance, in some examples, the power semiconductor die may include silicon carbide-based MOSFETs, located between a source contact and a drain contact to form, for instance, a vertical structure power semiconductor device. Aspects of the present disclosure are discussed with reference to silicon carbide-based MOSFET devices for purposes of illustration and discussion. Those of ordinary skill in the art, using the disclosures provided herein, will understand that the power semiconductor die may include other power semiconductor devices without deviating from the scope of the present disclosure, such as diodes (e.g., Schottky diodes, PiN diodes, etc.), insulated gate bipolar transistors, high electron mobility transistors, or other devices.

In some examples, an insulating layer may be formed on the power semiconductor die. The insulating material may be, for instance, a dielectric material. The dielectric material may be, in some embodiments, an underfill material. The underfill material may be, for instance, a composite material made up of a polymer (e.g., epoxy polymer) with filler and/or additional components.

The semiconductor die directly coupled to the first carrier substrate (e.g., in a flip chip configuration) may form a first assembly. According to examples of the present disclosure, the first assembly may be directly coupled to a second carrier substrate. For instance, the opposite surface of the semiconductor die to the surface directly coupled to the first carrier substrate may be directly coupled to the second carrier substrate. As used herein, the power semiconductor die is directly coupled to the second carrier substrate when the power semiconductor die is attached to the second carrier substrate (e.g., with or without an attach material such as solder, paste, sintered material, etc.) without any intervening structures, such as wire bonds, wire ribbons, clips or other structures. In some examples, the second carrier substrate may be the lead frame for the power semiconductor package and may include one or more conductive leads.

An encapsulating portion may be formed around at least a portion of the first carrier substrate, the second carrier substrate, and the power semiconductor die to form the power semiconductor package. In some examples, the dielectric material of the encapsulating portion may be the same as the dielectric material of the insulating layer on the power semiconductor die. In some examples, the dielectric material of the encapsulating portion may be different from the dielectric material of the insulating layer on the power semiconductor die. For instance, the dielectric material of the insulating layer may have a different dielectric constant (e.g., a lower dielectric constant) relative to the dielectric material of the encapsulating layer. In this way, the higher quality dielectric material may be used to form the insulating layer relative to the dielectric material of the encapsulating portion.

Aspects of the present disclosure provide a number of technical effects and benefits. For instance, directly coupling the power semiconductor die to both the first carrier substrate and the second carrier substrate provides at least two thermal dissipation paths for the power semiconductor die in the power semiconductor package. In addition, the power semiconductor die may be connected, for instance, to the lead frame of the power semiconductor package without the use of any wire bonds. The insulating layer formed on the power semiconductor die (e.g., the underfill material) may isolate the differing contacts of the power semiconductor devices on the power semiconductor die (e.g., the source contact and the drain contact) prior to coupling the power semiconductor die to the second carrier substrate. This can reduce the risk of any electrical short between the source contact and the drain contact due to dielectric material processing during encapsulation.

Aspects of the present disclosure are discussed with reference to silicon carbide-based semiconductor structures, such as silicon carbide-based MOSFETs. Those of ordinary skill in the art, using the disclosures provided herein, will understand that the power semiconductor packages according to example embodiments of the present disclosure may be used with any semiconductor material, such as other wide band gap semiconductor materials, without deviating from the scope of the present disclosure. Example wide band gap semiconductor materials include silicon carbide (e.g., 2.996 eV band gap for alpha silicon carbide at room temperature) and the Group III-nitrides (e.g., 3.36 eV band gap for gallium nitride at room temperature).

It will be understood that, although the terms first, second, third, etc. may be used herein to describe various elements, these elements should not be limited by these terms. These terms are only used to distinguish one element from another. For example, a first element could be termed a second element, and, similarly, a second element could be termed a first element, without departing from the scope of the present disclosure. As used herein, the term “and/or” includes any and all combinations of one or more of the associated listed items.

The terminology used herein is for the purpose of describing particular embodiments only and is not intended to be limiting of the invention. As used herein, the singular forms “a,” “an” and “the” are intended to include the plural forms as well, unless the context clearly indicates otherwise. It will be further understood that the terms “comprises” “comprising,” “includes” and/or “including” when used herein, specify the presence of stated features, integers, steps, operations, elements, and/or components, but do not preclude the presence or addition of one or more other features, integers, steps, operations, elements, components, and/or groups thereof.

Unless otherwise defined, all terms (including technical and scientific terms) used herein have the same meaning as commonly understood by one of ordinary skill in the art to which this invention belongs. It will be further understood that terms used herein should be interpreted as having a meaning that is consistent with their meaning in the context of this specification and the relevant art and will not be interpreted in an idealized or overly formal sense unless expressly so defined herein.

It will be understood that when an element such as a layer, region, or substrate is referred to as being “on” or extending “onto” another element, it may be directly on or extend directly onto the other element or intervening elements may also be present. In contrast, when an element is referred to as being “directly on” or extending “directly onto” another element, there are no intervening elements present, except in some examples an attach material (e.g., die-attach material, solder, paste, adhesive, sintered material or other material may be present. It will also be understood that when an element is referred to as being “connected” or “coupled” to another element, it may be directly connected or coupled to the other element or intervening elements may be present. In contrast, when an element is referred to as being “directly connected” or “directly coupled” to another element, there are no intervening elements present, except in some examples an attach material (e.g., die-attach material, solder, paste, adhesive, sintered material or other material may be present.

Relative terms such as “below” or “above” or “upper” or “lower” or “horizontal” or “lateral” or “vertical” may be used herein to describe a relationship of one element, layer or region to another element, layer or region as illustrated in the figures. It will be understood that these terms are intended to encompass different orientations of the device in addition to the orientation depicted in the figures.

Embodiments of the disclosure are described herein with reference to cross-section illustrations that are schematic illustrations of idealized embodiments of the disclosure. The thickness of layers and regions in the drawings may be exaggerated for clarity. Additionally, variations from the shapes of the illustrations as a result, for example, of manufacturing techniques and/or tolerances, are to be expected. Thus, embodiments of the disclosure should not be construed as limited to the particular shapes of regions illustrated herein but are to include deviations in shapes that result, for example, from manufacturing. Similarly, it will be understood that variations in the dimensions are to be expected based on standard deviations in manufacturing procedures. As used herein, “approximately” or “about” includes values within 10% of the nominal value.

Like numbers refer to like elements throughout. Thus, the same or similar numbers may be described with reference to other drawings even if they are neither mentioned nor described in the corresponding drawing. Also, elements that are not denoted by reference numbers may be described with reference to other drawings.

Some embodiments of the invention are described with reference to semiconductor layers and/or regions which are characterized as having a conductivity type such as n type or p type, which refers to the majority carrier concentration in the layer and/or region. Thus, N type material has a majority equilibrium concentration of negatively charged electrons, while P type material has a majority equilibrium concentration of positively charged holes. Some material may be designated with a “+” or “−” (as in N+, N−, P+, P−, N++, N−−, P++, P−−, or the like), to indicate a relatively larger (“+”) or smaller (“−”) concentration of majority carriers compared to another layer or region. However, such notation does not imply the existence of a particular concentration of majority or minority carriers in a layer or region.

In the drawings and specification, there have been disclosed typical embodiments and, although specific terms are employed, they are used in a generic and descriptive sense only and not for purposes of limitation of the scope set forth in the following claims.

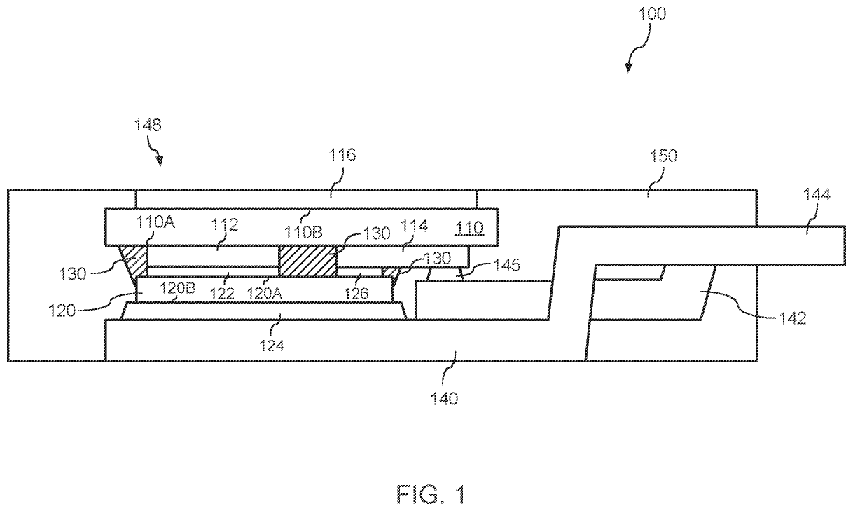

FIG. 1 depicts an example power semiconductor package 100 according to example embodiments of the present disclosure. FIG. 1 is intended to represent structures for identification and description and is not intended to represent the structures to physical scale. The power semiconductor package 100 includes a first carrier substrate 110. The first carrier substrate 110 may be an AMB substrate, a DBC substrate, or other suitable substrate. The first carrier substrate 110 may include a dielectric and/or a ceramic substrate, such as alumina, aluminum nitride, silicon nitride, or other suitable dielectric material. The first carrier substrate 110 may have a first surface 110A and an opposing second surface 110B. The first carrier substrate 110 may have one or more thermally and/or electrically conductive pads on the first surface 110A. For instance, the first carrier substrate 110 may have a first conductive pad 112 and a second conductive pad 114 on the first surface 110A. The first carrier substrate 110 may have a thermally conductive cooling layer 116 (e.g., a copper pad) on the second surface 110B. The first conductive pad 112, the second conductive pad 114, and/or the thermally conductive cooling layer 116 may be copper, silver, gold, titanium or other conductive material.

The power semiconductor package 100 includes a power semiconductor die 120. The power semiconductor die 120 may include one or more power semiconductor devices, such as one or more transistors, diodes, thyristors, or other devices. In some examples, the power semiconductor die 120 may include a silicon carbide-based MOSFET. The power semiconductor die 120 may include a first contact 122 (e.g., a source contact) disposed on a first surface 120A of the power semiconductor die 120. The power semiconductor die 120 may include a second contact 124 (e.g., a drain contact) on a second surface 120B of the power semiconductor die that is opposite the first surface 120A. In this way, the power semiconductor die 120 may include a vertical power semiconductor device between the first contact 122 and the second contact 124.

The power semiconductor die 120 may include additional contacts. For instance, the power semiconductor die 120 may include one or more third contacts 126. The third contact(s) 126 may be on the same surface (e.g., the first surface 120A) of the power semiconductor die 120 as the first contact 122. The third contact(s) 126 may include, for instance, a gate contact and/or a kelvin contact.

The power semiconductor die 120 may be directly coupled to the first carrier substrate 110. In some examples, the power semiconductor die 120 is directly coupled to the first carrier substrate 110 in a flip chip configuration. For instance, a first surface 120A of the power semiconductor die 120 that includes the first contact 122 (e.g., a source contact) and the third contact 126 (e.g., a gate contact) may be directly coupled to the first carrier substrate 110. A second surface 120B that is opposite the first surface 120A of the semiconductor die 120 that includes the second contact 124 (e.g., the drain contact) may be facing away from the first carrier substrate 110.

More particularly, the first contact 122 (e.g., the source contact) may be directly coupled to the first conductive pad 112 of the first carrier substrate 110 with or without a die-attach material (e.g., solder, paste, sintered material, etc.). The first contact 122 (e.g., the source contact) may be directly coupled to the first conductive pad 112 of the first carrier substrate 110 without the use of wire bonds. The third contact 126 (e.g., the gate contact) may be directly coupled to the second conductive pad 114 of the first carrier substrate 110 with or without a die-attach material (e.g., solder, paste, sintered material, etc.). The third contact 126 (e.g., the gate contact) may be directly coupled to the second conductive pad 114 of the first carrier substrate 110 without the use of wire bonds.

The second contact 124 (e.g., the drain contact) may be directly coupled to a second carrier substrate 140 with or without a die-attach material (e.g., solder, paste, sintered material, etc.). The second contact 124 (e.g., the drain contact) may be directly coupled to the second carrier substrate 140 without the use of wire bonds. The second carrier substrate 140 may include or be coupled to one or more conductive leads, such as conductive lead 142 and conductive lead 144. The conductive lead 142 and the conductive lead 144 may facilitate connection of the power semiconductor package to an external component, such as one or more circuits. The second carrier substrate 140 may be, for instance, a lead frame (e.g., a copper lead frame) of the power semiconductor package 100. In some embodiments, the second carrier substrate 140 may be, for instance, a substrate (e.g., a DBC substrate or an AMB substrate) that is coupled to one or more conductive leads of the power semiconductor package 100.

The one or more conductive pads on the first surface 110A of the first carrier substrate 110, such as conductive pad 112 and conductive pad 114, may also be coupled to the second carrier substrate 140 and/or to one or more conductive leads of (e.g., conductive lead 142) associated with the second carrier substrate 140. In some examples, the conductive pad 114 on the first surface 110A of the first carrier substrate 110 is coupled to the second carrier substrate 140 and/or to one or more conductive leads of the second carrier substrate 140 using an interconnection 145. The interconnection 145 may include, in some embodiments, an attach material (e.g., solder, paste, sintered material, etc.). The conductive pad 112 on the first surface 110A of the first carrier substrate 110 may similarly be coupled to the second carrier substrate 140 and/or to one or more conductive leads of the second carrier substrate 140 using an interconnection (not illustrated). In some embodiments, the first conductive pad 112 may be coupled to a first conductive lead (e.g., conductive lead 142) of the second carrier substrate 140. The second conductive pad 114 may be coupled to a second conductive lead of the second carrier substrate 140. In this way, the first contact 122 (e.g., the source contact) and the third contact 126 (e.g., the gate contact 116) of the power semiconductor die 120 are coupled to conductive leads of the second carrier substrate 140 for connection to external components.

In some examples, the power semiconductor package 100 may include an insulating layer 130 on the power semiconductor die 120. For instance, the insulating layer 130 may be on the first surface 120A of the power semiconductor die 120 having the first contact 122 (e.g., a source contact) and the third contact 126 (e.g., a gate contact). In some examples, the insulating layer 130 may extend between the power semiconductor die 120 and the first carrier substrate 110, such that the insulating layer 130 fills any gaps between the power semiconductor die 120 and the first carrier substrate 110. The insulating layer 130 may not extend to or may not be on the second surface 120B of the power semiconductor die 120. In some examples, the insulating layer 130 includes an underfill material. The underfill material may be, for instance, a polymer-based material, such as an epoxy polymer material. The underfill material may include a filler or other components, such as a flowing agent, adhesive agent, etc.

The semiconductor package 100 may further include an encapsulating portion 150. The encapsulating portion 150 may form a housing for the power semiconductor package 100. The encapsulating portion 150 may be formed by a molding process such that the encapsulating portion is provided at least partially around the first carrier substrate 110, the power semiconductor die 120, and the second carrier substrate 140. The material of the encapsulating portion 150 may electrically isolate the components within the power semiconductor package 100 from each other. The material of the encapsulating portion 150 may be a dielectric material. Example materials for the encapsulating portion 150 may include an epoxy material or an epoxy mold compound (EMC).

In some examples, the dielectric material of the encapsulating portion 150 may be the same as the dielectric material of the insulating layer 130. In some examples, the dielectric material of the encapsulating portion 150 may be different from the dielectric material of the insulating layer 130 on the power semiconductor die 120. For instance, the dielectric material of the insulating layer 130 may have a different dielectric constant (e.g., a lower dielectric constant) relative to the dielectric material of the encapsulating portion 150. In this way, a higher quality dielectric material may be used to form the insulating layer 130 relative to the dielectric material of the encapsulating portion 150.

As shown in FIG. 1, the thermally conductive cooling layer 116 on the first carrier substrate 110 is exposed through the encapsulating portion 150 of the power semiconductor package 100, such as through an opening 148 in the encapsulating portion 150. As such, the thermally conductive cooling layer 116 may provide a second thermally conductive path for cooling of the power semiconductor die 120 in the power semiconductor package 100. More particularly, the first thermally conductive path may be provided through the second carrier substrate 140 and the one or more conductive leads, such as conductive lead 142 and conductive lead 144. The second thermally conductive path may be provided through opening 148 in the encapsulating portion 150 that leaves at least a portion of the thermally conductive cooling layer 116 exposed through the encapsulating portion 150. The thermally conductive cooling layer 116 may be coupled to a heat sink and/or may provide a thermally conductive path to an ambient environment of the power semiconductor package 100.

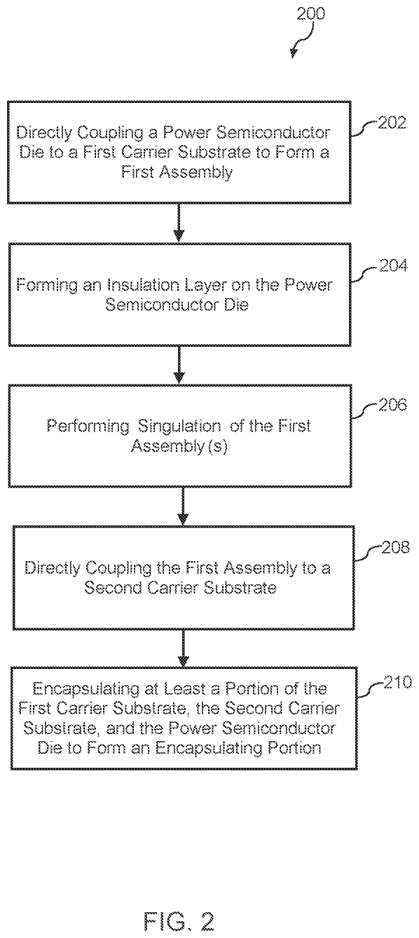

FIG. 2 depicts a flow chart of an example method for fabricating a power semiconductor package according to example embodiments of the present disclosure, such as the power semiconductor packages depicted in FIGS. 1, 11, and 12. FIG. 2 depicts steps performed in a particular order for purposes of illustration and discussion. Those of ordinary skill in the art, using the disclosures provided herein, will understand that the various steps provided in this disclosure may be omitted, rearranged, expanded, include steps not illustrated, and/or modified in various ways without deviating from the scope of the present disclosure.

At 202, the method 200 may include directly coupling a power semiconductor die to a first carrier substrate to form a first assembly. For instance, in some examples, a plurality of power semiconductor die may be subjected to singulation from a semiconductor wafer to provide a plurality of individual power semiconductor die. Each individual power semiconductor die may be, for instance, the power semiconductor die 120 discussed with reference to FIG. 1. Each power semiconductor die may include one or more power semiconductor devices, such as transistors, diodes, thyristors, etc. As described above, the power semiconductor die may include wide band gap semiconductor. The power semiconductor die may include a vertical power semiconductor device including a first contact arranged on a first surface and a second contact arranged on an opposing second surface of the power semiconductor die. As an example, the power semiconductor die may include one or more silicon carbide-based MOSFETs. In some examples, each of the plurality of power semiconductor die may be directly coupled to a carrier sheet or card having a plurality of first carrier substrates arranged in a grid or an array.

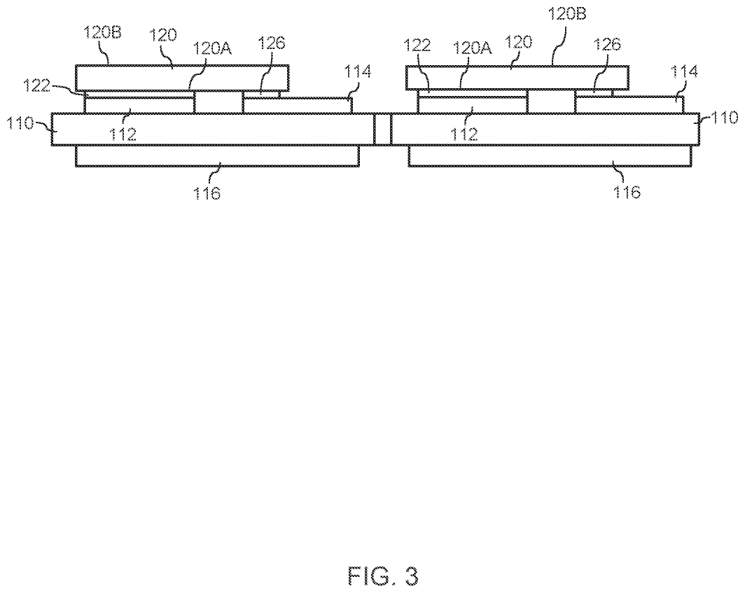

FIG. 3 depicts the direct coupling of a plurality of power semiconductor die 120 to a carrier sheet having a plurality of first carrier substrates 110 according to example embodiments of the present disclosure. As shown, the power semiconductor die are directly coupled to the first carrier substrates 110 (e.g., with or without an attach material) using a flip chip configuration. In the flip chip configuration, the first surface 120A of the power semiconductor die including a first contact 122 (e.g., a source contact) and the third contact 126 (e.g., a gate contact) are “flipped” and directly coupled to conductive pads on the first carrier substrate 110. For instance, the first contact 122 (e.g., a source contact) is coupled to a first conductive pad 112. The third contact 126 (e.g., a gate contact) is coupled to a second conductive pad 114. No wire bonds are used to couple the power semiconductor die 120 to the first carrier substrates 110. The combination of the power semiconductor die 120 directly coupled to one of the plurality of first carrier substrates 110 may be a first assembly 160.

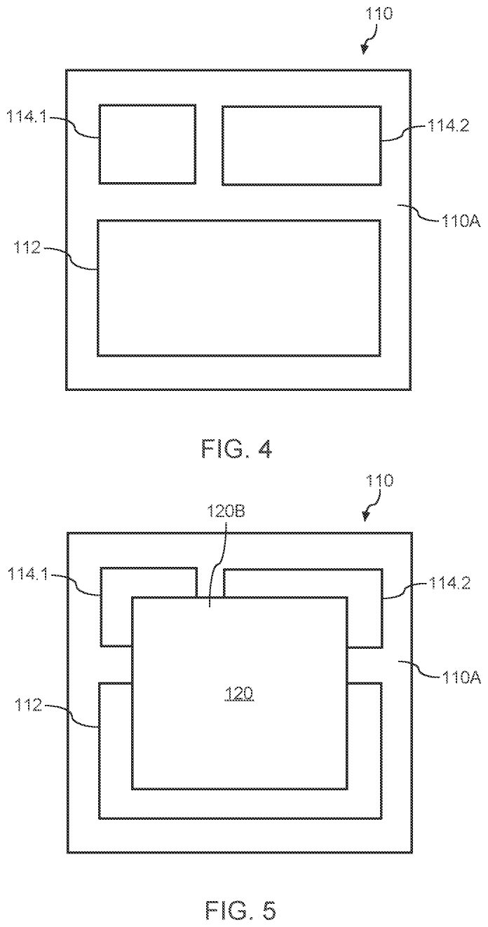

FIGS. 4 and 5 depict plan views of the example direct coupling of a power semiconductor die 120 to a first carrier substrate 110 using a flip chip configuration according to example embodiments of the present disclosure. FIG. 4 depicts a plan view of the first surface 110A of an example first carrier substrate 110. The first carrier substrate 110 includes a patterned arrangement of conductive pads, including first conductive pad 112 and second conductive pads 114.1 and 114.2. The first conductive pad 112 may be for direct coupling of a source contact of a power semiconductor die 120. The second conductive pad 114.1 may be for direct coupling of a gate contact of a power semiconductor die 120. The second conductive pad 114.2 may be for direct coupling of other contacts of a power semiconductor die 120 (e.g., a kelvin contact).

FIG. 5 depicts a plan view of the power semiconductor die 120 directly coupled to the first carrier substrate 110. As shown, the power semiconductor die 120 is flipped so that the first surface 120A (not illustrated) including the first contact 122 (e.g. source contact) and the third contact 126 (e.g., gate contact) are face down and coupled to the first carrier substrate 110. The second surface 120B of the power semiconductor die 120 including the second contact (e.g., drain contact) is face up facing a direction away from the first carrier substrate 110.

FIGS. 4 and 5 depict one example pattern of conductive pads for the first carrier substrate 110 for purposes of illustration and discussion. Those of ordinary skill in the art, using the disclosures provided herein, will understand that the first carrier substrate 110 may include a variety of different patterns or arrangements of conductive pads without deviating from the scope of the present disclosure.

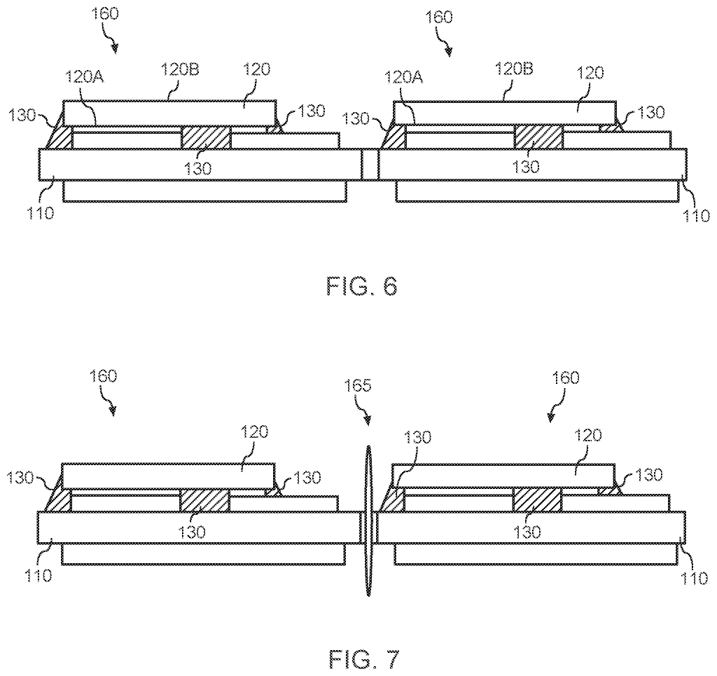

Referring to FIG. 2 at 204, the method 200 may include forming an insulating layer on the power semiconductor die of the first assembly. For instance, as shown in FIG. 6, an insulating layer 130 may be formed on the first assembly 160. More particularly, the insulating layer 130 may be formed on the power semiconductor die 120 to cover at least a portion of the first contact 122 (e.g., source contact) and the third contact 126 (e.g., gate contact). The insulating layer 130 may fill any gaps between the power semiconductor die 120 and the first carrier substrate 110. The insulating layer 130 may only be on only one surface of the power semiconductor die 120, such as the first surface 120A of the power semiconductor die 120 directly coupled to the first carrier substrate 110. In some examples, the insulating layer 130 includes an underfill material. The underfill material may be, for instance, a polymer-based material, such as an epoxy polymer material. The underfill material may include a filler or other components, such as a flowing agent, adhesive agent, etc.

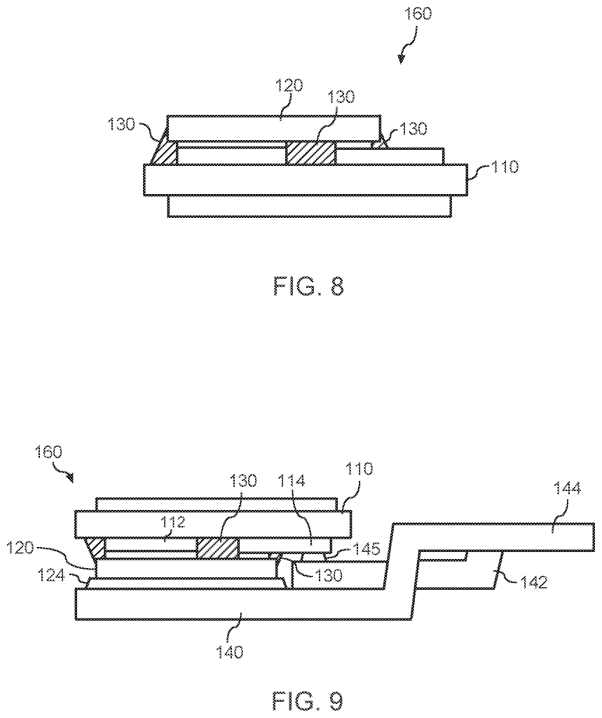

Referring to FIG. 2 at 206, the method 200 may include performing singulation of the first assembly(s). For instance, as shown in FIG. 7, a cutting tool 165 may be used to separate the first assembly(s) 160 from one another in the carrier sheet. FIG. 8 depicts an example individual first assembly 160 after singulation. Each individual first assembly 160 includes a power semiconductor die 120 directly coupled to a first carrier substrate 110, for instance, in a flip chip configuration, with an insulating layer 130 on the power semiconductor die 120.

Referring to FIG. 2 at 208, the method 200 may include directly coupling the first assembly to a second carrier substrate. For instance, as shown in FIG. 9, the first assembly 160 is “flipped” and directly coupled to a second carrier substrate 140 that includes one or more conductive leads, such as conductive lead 142 and conductive lead 144. The second carrier substrate 140, in some examples, may be a lead frame for a power semiconductor package. As shown in FIG. 9, the second contact 124 (e.g., drain contact) of the power semiconductor die 120 is directly coupled to the second carrier substrate (e.g., with or without an attach material) without the use of wire bonds. In addition, one or more conductive pads on the first carrier substrate 110 are also coupled to the second carrier substrate 140. For instance, referring to FIGS. 4 and 5 conductive pad 114.1 may be coupled to the second carrier substrate 140 and/or to one or more conductive leads (e.g., conductive lead 142) of the second carrier substrate 140 through an interconnection (e.g., interconnection 145, such as an attach material). The conductive pad 114.2 may be coupled to the second carrier substrate 140 and/or to one or more conductive leads of the second carrier substrate 140 through an interconnection (e.g., attach material). The conductive pad 112 may be coupled to the second carrier substrate 140 and/or to one or more conductive leads of the second carrier substrate 140 through an interconnection (e.g., attach material). In this way, the power semiconductor die 120 is directly coupled to two different carrier substrates without wire bonds to establish connections to conductive leads of a power semiconductor package.

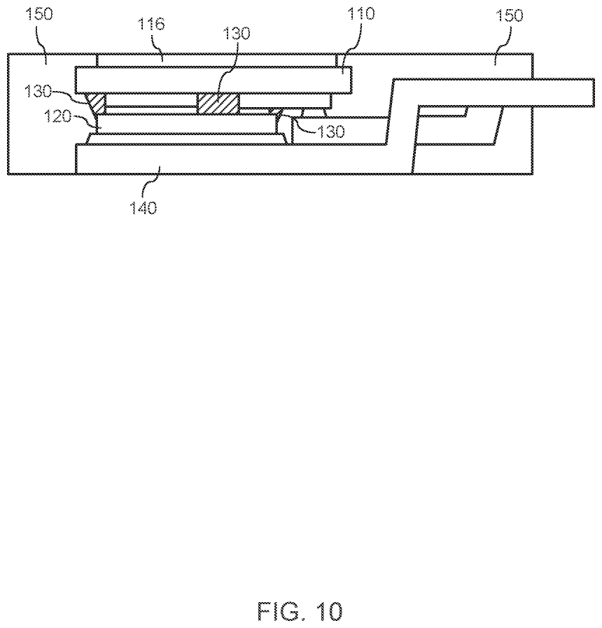

Referring to FIG. 2 at 210, the method 200 may include encapsulating at least a portion of the first carrier substrate, the second carrier substrate, and the power semiconductor die to form an encapsulating portion. For instance, as shown in FIG. 10, an encapsulating portion 150 may be formed at least partially covering the first carrier substrate 110, the power semiconductor die 120, the insulating layer 130, and the second carrier substrate 140. The encapsulating portion 150 may form a housing for the power semiconductor package 100. The encapsulating portion 150 may be formed by a molding process such that the encapsulating portion is provided at least partially around the first carrier substrate 110, the semiconductor die 120, and the second carrier substrate 140. The material of the encapsulating portion 150 may electrically isolate the components within the encapsulating portion 150 from each other. The material of the encapsulating portion 150 may be a dielectric material. Example materials for the encapsulating portion 150 may include an epoxy material or an epoxy mold compound (EMC).

In some examples, the dielectric material of the encapsulating portion 150 may be the same as the dielectric material of the insulating layer 130. In some examples, the dielectric material of the encapsulating portion 150 may be different from the dielectric material of the insulating layer 130 on the power semiconductor die 120. For instance, the dielectric material of the insulating layer 130 may have a different dielectric constant (e.g., a lower dielectric constant) relative to the dielectric material of the encapsulating portion 150. In this way, a higher quality dielectric material may be used to form the insulating layer 130 relative to the dielectric material of the encapsulating portion 150.

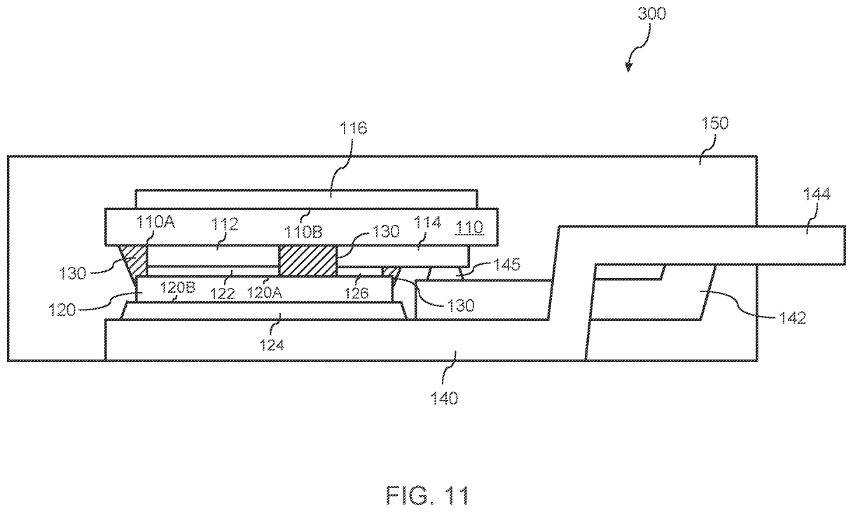

Variations and modifications may be made to the example power semiconductor packages described herein without deviating from the scope of the present disclosure. For instance, FIG. 11 depicts a power semiconductor package 300 that is similar to the power semiconductor package 100 of FIG. 1. FIG. 11 is intended to represent structures for identification and description and is not intended to represent the structures to physical scale. For instance, the power semiconductor package 300 includes a first carrier substrate 110. The first carrier substrate 110 includes one or more conductive pads (e.g., conductive pads 112 and 114) and a thermally conductive cooling layer 116. The power semiconductor package 300 includes a second carrier substrate 140. The second carrier substrate 140 includes one or more conductive leads (e.g., conductive lead 142 and conductive lead 144) for the power semiconductor package 300. The power semiconductor package 300 includes a power semiconductor die 120 having a first surface 120A and an opposing second surface 120B. The first surface 120A of the power semiconductor die 120 is directly coupled to the first carrier substrate 110 (e.g., in a flip chip configuration). The second surface 120B of the power semiconductor die 120 is directly coupled to the second carrier substrate 140.

In the power semiconductor package 300, the first carrier substrate 110 includes a thermally conductive cooling layer 116 on the second surface 110B of the first carrier substrate 110 opposite the first surface 110A with the one or more conductive pads (e.g., conductive pads 112 and 114). In the example of FIG. 11, the thermally conductive cooling layer 116 is covered by the encapsulating portion 150 instead of being exposed through an opening of the encapsulating portion 150.

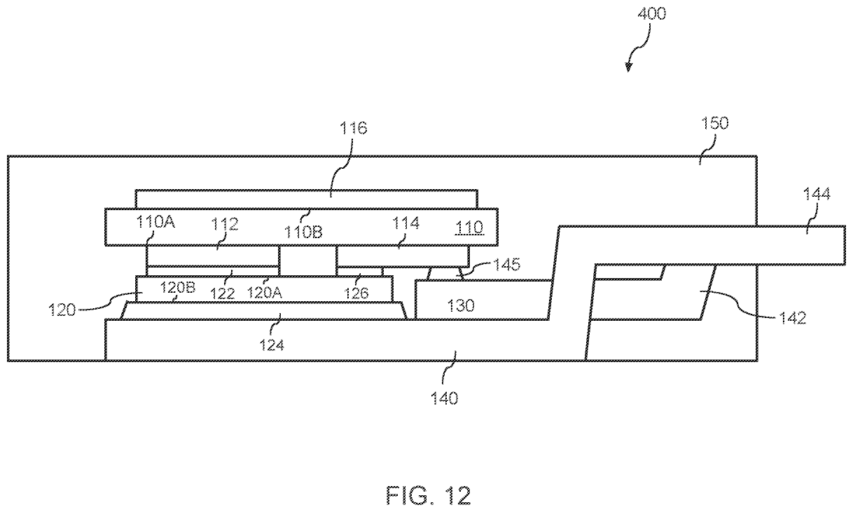

FIG. 12 depicts a power semiconductor package 400 that is similar to the power semiconductor package 100 of FIG. 1 and the power semiconductor package 300 of FIG. 11. FIG. 12 is intended to represent structures for identification and description and is not intended to represent the structures to physical scale. The power semiconductor package 400 includes a first carrier substrate 110. The first carrier substrate 110 includes one or more conductive pads (e.g., conductive pads 112 and 114) and a thermally conductive cooling layer 116. The power semiconductor package 400 includes a second carrier substrate 140. The second carrier substrate 140 includes one or more conductive leads (e.g., conductive lead 142 and conductive lead 144) for the power semiconductor package 400. The power semiconductor package 400 includes a power semiconductor die 120 having a first surface 120A and an opposing second surface 120B.

The first surface 120A of the power semiconductor die 120 is directly coupled to the first carrier substrate 110 (e.g., in a flip chip configuration). The second surface 120B of the power semiconductor die 120 is directly coupled to the second carrier substrate 140. The power semiconductor package 400 does not include a separate insulating layer 130 on the power semiconductor die 120. Rather, the encapsulating portion 150 of the power semiconductor package 400 surrounds the power semiconductor die 120.

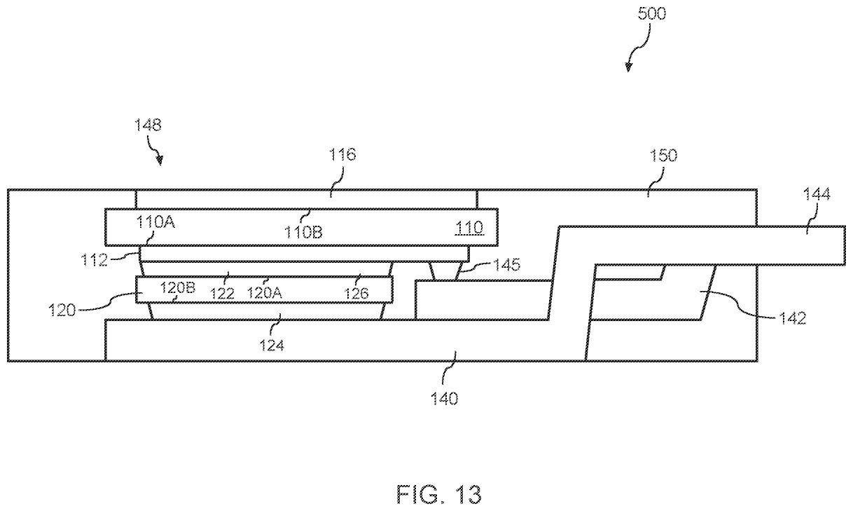

FIG. 13 depicts a power semiconductor package 500 that is similar to the power semiconductor package 100 of FIG. 1. FIG. 13 is intended to represent structures for identification and description and is not intended to represent the structures to physical scale. For instance, the power semiconductor package 500 includes a first carrier substrate 110. The first carrier substrate 110 includes one or more conductive pads (e.g., conductive pad 112) and a thermally conductive cooling layer 116. The power semiconductor package 500 includes a second carrier substrate 140. The second carrier substrate 140 includes one or more conductive leads (e.g., conductive lead 142 and conductive lead 144) for the power semiconductor package 500. The power semiconductor package 500 includes a power semiconductor die 120. In the example of FIG. 13, the power semiconductor die 120 may include one or more Schottky diodes, such as one or more silicon carbide-based Schottky diodes. The power semiconductor die 120 has a first surface 120A and an opposing second surface 120B. The first surface 120A of the power semiconductor die 120 is directly coupled to the first carrier substrate 110 (e.g., in a flip chip configuration) such that a first contact 122 (e.g., an anode contact) is directly coupled to the first carrier substrate 110. The second surface 120B of the power semiconductor die 120 is directly coupled to the second carrier substrate 140 such that a second contact 124 (e.g., a cathode contact) is directly coupled to the second carrier substrate 140. The power semiconductor package 500 includes an encapsulating portion 150. The thermally conductive cooling layer 116 is exposed through an opening 148 in the encapsulating portion 150.

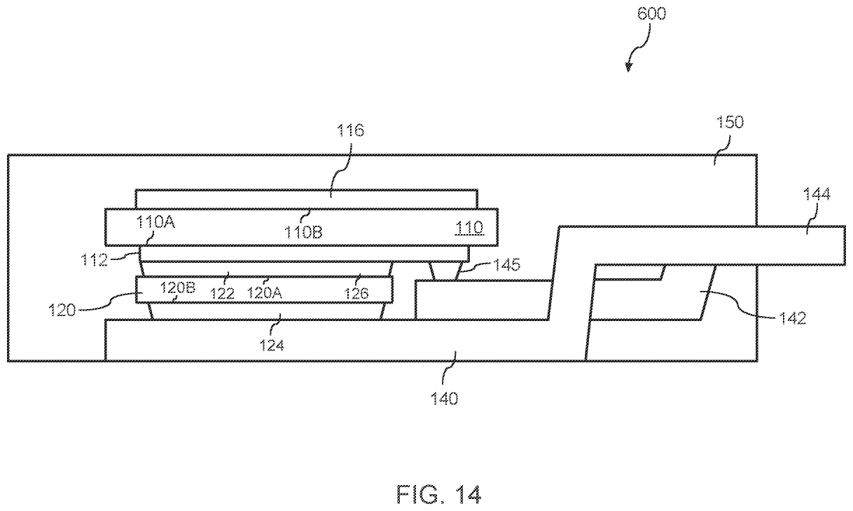

FIG. 14 depicts a power semiconductor package 600 that is similar to the power semiconductor package 500 of FIG. 13. FIG. 14 is intended to represent structures for identification and description and is not intended to represent the structures to physical scale. For instance, the power semiconductor package 600 includes a first carrier substrate 110. The first carrier substrate 110 includes one or more conductive pads (e.g., conductive pad 112) and a thermally conductive cooling layer 116. The power semiconductor package 600 includes a second carrier substrate 140. The second carrier substrate 140 includes one or more conductive leads (e.g., conductive lead 142 and conductive lead 144) for the power semiconductor package 600. The power semiconductor package 600 includes a power semiconductor die 120. In the example of FIG. 14, the power semiconductor die 120 may include one or more Schottky diodes, such as one or more silicon carbide-based Schottky diodes. The power semiconductor die 120 has a first surface 120A and an opposing second surface 120B. The first surface 120A of the power semiconductor die 120 is directly coupled to the first carrier substrate 110 (e.g., in a flip chip configuration) such that a first contact 122 (e.g., an anode contact) is directly coupled to the first carrier substrate 110. The second surface 120B of the power semiconductor die 120 is directly coupled to the second carrier substrate 140 such that a second contact 124 (e.g., a cathode contact) is directly coupled to the second carrier substrate 140. The power semiconductor package 600 includes an encapsulating portion 150. A thermal cooling layer 116 is covered by the encapsulating portion 150.

Example aspects of the present disclosure are provided in the following paragraphs, the examples of which may be combined to form various different embodiments of the present disclosure.

One example embodiment is directed to a power semiconductor package. The power semiconductor package may include a first carrier substrate. The first carrier substrate may include one or more conductive pads. The power semiconductor package may include a second carrier substrate. The second carrier substrate may include one or more conductive leads. The power semiconductor package may include a power semiconductor die having a first surface and an opposing second surface. The first surface of the power semiconductor die may be directly coupled to the first carrier substrate. The second surface of the power semiconductor die may be directly coupled to the second carrier substrate.

Some examples are directed to the power semiconductor package of any preceding paragraph, wherein the power semiconductor die includes a first contact on the first surface and a second contact on the second surface.

Some examples are directed to the power semiconductor package of any preceding paragraph, wherein the first contact is directly coupled to at least one of the one or more conductive pads of the first carrier substrate, wherein the second contact is directly coupled to the second carrier substrate.

Some examples are directed to the power semiconductor package of any preceding paragraph, wherein the power semiconductor die comprises a third contact on the first surface.

Some examples are directed to the power semiconductor package of any preceding paragraph, wherein the one or more conductive pads of the first carrier substrate comprises a first conductive pad and a second conductive pad, wherein the first contact is directly coupled to the first conductive pad and the third contact is directly coupled to the second conductive pad.

Some examples are directed to the power semiconductor package of any preceding paragraph, wherein the first carrier substrate is coupled to one or more second conductive leads of the power semiconductor package.

Some examples are directed to the power semiconductor package of any preceding paragraph, wherein the power semiconductor die is directly coupled to the first carrier substrate in a flip chip configuration.

Some examples are directed to the power semiconductor package of any preceding paragraph, wherein the first carrier substrate comprises a direct bonded copper (DBC) substrate or an active metal brazed (AMB) substrate.

Some examples are directed to the power semiconductor package of any preceding paragraph, wherein the second carrier substrate comprises a lead frame for the power semiconductor package.

Some examples are directed to the power semiconductor package of any preceding paragraph, wherein the first carrier substrate comprises a first surface and an opposing second surface, wherein the one or more conductive pads are on the first surface of the first carrier substrate, wherein the first carrier substrate comprises a thermally conductive cooling layer on the second surface.

Some examples are directed to the power semiconductor package of any preceding paragraph, wherein the thermally conductive cooling layer is exposed through an encapsulating portion of the power semiconductor package.

Some examples are directed to the power semiconductor package of any preceding paragraph, wherein the thermally conductive cooling layer is covered by an encapsulating portion of the power semiconductor package.

Some examples are directed to the power semiconductor package of any preceding paragraph, wherein the power semiconductor package further comprises an insulating layer on the first contact of the power semiconductor die.

Some examples are directed to the power semiconductor package of any preceding paragraph, wherein the insulating layer comprises a first dielectric material.

Some examples are directed to the power semiconductor package of any preceding paragraph, wherein the power semiconductor package further comprises an encapsulating portion, the encapsulating portion comprising a second dielectric material.

Some examples are directed to the power semiconductor package of any preceding paragraph, wherein the first dielectric material is different from the second dielectric material.

Some examples are directed to the power semiconductor package of any preceding paragraph, wherein the first dielectric material has a first dielectric constant, and the second dielectric material has a second dielectric constant, the first dielectric constant being different from the second dielectric constant.

Some examples are directed to the power semiconductor package of any preceding paragraph, wherein the first dielectric material is the same as the second dielectric material.

Some examples are directed to the power semiconductor package of any preceding paragraph, wherein the first dielectric material is an underfill material.

Some examples are directed to the power semiconductor package of any preceding paragraph, wherein the power semiconductor die comprises a wide band gap semiconductor.

Some examples are directed to the power semiconductor package of any preceding paragraph, wherein the wide band gap semiconductor is silicon carbide.

Some examples are directed to the power semiconductor package of any preceding paragraph, wherein the power semiconductor package does not include any wire bonds to the power semiconductor die.

Some examples are directed to the power semiconductor package of any preceding paragraph, wherein the power semiconductor die comprises a silicon carbide-based MOSFET.

Some examples are directed to the power semiconductor package of any preceding paragraph, wherein the power semiconductor die comprises a silicon carbide-based Schottky diode.

Another example embodiment of the present disclosure is directed to a power semiconductor package. The power semiconductor package may include a first carrier substrate. The power semiconductor package may include a second carrier substrate. The power semiconductor package may include a power semiconductor die having a first surface and an opposing second surface. The power semiconductor die may include a source contact and a gate contact on the first surface. The power semiconductor die may include a drain contact on the second surface. The first surface of the power semiconductor die may be directly coupled to the first carrier substrate in a flip chip configuration such that the source contact and the gate contact are directly coupled to the first carrier substrate. The second surface of the power semiconductor die may be directly coupled to the second carrier substrate.

Some examples are directed to the power semiconductor package of any preceding paragraph, wherein the power semiconductor package does not include any wire bonds to the power semiconductor die.

Some examples are directed to the power semiconductor package of any preceding paragraph, wherein the first carrier substrate comprises a direct bonded copper (DBC) substrate or an active metal brazed (AMB) substrate.

Some examples are directed to the power semiconductor package of any preceding paragraph, wherein the second carrier substrate comprises a lead frame for the power semiconductor package.

Some S examples are directed to the power semiconductor package of any preceding paragraph, wherein the power semiconductor package further comprises an insulating layer on the first surface of the power semiconductor die.

Some examples are directed to the power semiconductor package of any preceding paragraph, wherein the power semiconductor package further comprises an encapsulating portion.

Some examples are directed to the power semiconductor package of any preceding paragraph, wherein the insulating layer comprises a first dielectric material and the encapsulating portion comprises a second dielectric material.

Some examples are directed to the power semiconductor package of any preceding paragraph, wherein the first dielectric material is different from the second dielectric material.

Some examples are directed to the power semiconductor package of any preceding paragraph, wherein the first dielectric material is the same as the second dielectric material.

Some examples are directed to the power semiconductor package of any preceding paragraph, wherein the first carrier substrate comprises a thermally conductive cooling layer exposed through the encapsulating portion.

Some examples are directed to the power semiconductor package of any preceding paragraph, wherein the first carrier substrate comprises a thermally conductive cooling layer that is covered by the encapsulating portion.

Another example embodiment of the present disclosure is directed to a power semiconductor package. The power semiconductor package may include a first carrier substrate. The power semiconductor package may include a second carrier substrate. The power semiconductor package may include a power semiconductor die having a first surface and an opposing second surface. The power semiconductor die may include a source contact and a gate contact on the first surface. The power semiconductor die may include a drain contact on the second surface. The power semiconductor package may include an insulating layer on the first surface of the semiconductor die. The power semiconductor package may include an encapsulating portion. The first surface of the power semiconductor die may be directly coupled to the first carrier substrate. The second surface of the power semiconductor die may be directly coupled to the second carrier substrate.

Some examples are directed to the power semiconductor package of any preceding paragraph, wherein the insulating layer comprises a first dielectric material and the encapsulating portion comprises a second dielectric material.

Some examples are directed to the power semiconductor package of any preceding paragraph, wherein the first dielectric material is different from the second dielectric material.

Some examples are directed to the power semiconductor package of any preceding paragraph, wherein the first dielectric material is the same as the second dielectric material.

Some examples are directed to the power semiconductor package of any preceding paragraph, wherein the first carrier substrate comprises a thermally conductive cooling layer exposed through the encapsulating portion.

Some examples are directed to the power semiconductor package of any preceding paragraph, wherein the first carrier substrate comprises a thermally conductive cooling layer covered by the encapsulating portion.

Another example embodiment of the present disclosure is directed to a method of fabricating a power semiconductor package. The method may include directly coupling a power semiconductor die to a first carrier substrate to form a first assembly. The method may include directly coupling the first assembly to a second carrier substrate. The second carrier substrate may include one or more conductive leads. The method may include encapsulating at least a portion of the first carrier substrate, the second carrier substrate, and the power semiconductor die to form an encapsulating portion.

Some examples are directed to a method of any preceding paragraph, wherein directly connecting the power semiconductor die to a first carrier substrate comprises directly connecting the power semiconductor die to the first carrier substrate in a flip chip configuration.

Some examples are directed to a method of any preceding paragraph, wherein directly connecting the first assembly to a second carrier substrate comprises directly connecting the first assembly to the second carrier substrate without wire bonds.

Some examples are directed to a method of any preceding paragraph, wherein the method further comprises forming an insulating layer on the power semiconductor die.

Some examples are directed to a method of any preceding paragraph, wherein forming an insulating layer on the power semiconductor die comprises forming the insulating layer on the power semiconductor die prior to directly connecting the first assembly to the second carrier substrate.

Some examples are directed to a method of any preceding paragraph, wherein the insulating layer comprises a first dielectric material and the encapsulating portion comprises a second dielectric material.

Some examples are directed to a method of any preceding paragraph, wherein the first dielectric material is different from the second dielectric material.

Some examples are directed to a method of any preceding paragraph, wherein the first dielectric material is the same as the second dielectric material.

Some examples are directed to a method of any preceding paragraph, wherein the first carrier substrate comprises a thermally conductive cooling layer.

Some examples are directed to a method of any preceding paragraph, wherein encapsulating at least a portion of the first carrier substrate, the second carrier substrate, and the power semiconductor die to form an encapsulating portion comprises leaving at least a portion of the thermally conductive cooling layer exposed through the encapsulating portion.

Some examples are directed to a method of any preceding paragraph, wherein encapsulating at least a portion of the first carrier substrate, the second carrier substrate, and the power semiconductor die to form an encapsulating portion comprises covering the thermally conductive cooling layer with the encapsulating portion.

Some examples are directed to a method of any preceding paragraph, wherein the first carrier substrate comprises a direct bonded copper (DBC) substrate or an active metal brazed (AMB) substrate.

Some examples are directed to a method of any preceding paragraph, wherein the second carrier substrate comprises a lead frame for the power semiconductor package.

Some examples are directed to a method of any preceding paragraph, wherein the power semiconductor die comprises a wide band gap semiconductor.

Some examples are directed to a method of any preceding paragraph, wherein the wide band gap semiconductor is silicon carbide.

Some examples are directed to a method of any preceding paragraph, wherein the power semiconductor die comprises a silicon carbide-based MOSFET.

Some examples are directed to a method of any preceding paragraph, wherein the power semiconductor die comprises a silicon carbide-based Schottky diode.

While the present subject matter has been described in detail with respect to specific example embodiments thereof, it will be appreciated that those skilled in the art, upon attaining an understanding of the foregoing may readily produce alterations to, variations of, and equivalents to such embodiments. Accordingly, the scope of the present disclosure is by way of example rather than by way of limitation, and the subject disclosure does not preclude inclusion of such modifications, variations and/or additions to the present subject matter as would be readily apparent to one of ordinary skill in the art.

1. A power semiconductor package, comprising:
a first carrier substrate, the first carrier substrate comprising one or more conductive pads;
a second carrier substrate, the second carrier substrate comprising one or more conductive leads; and
a power semiconductor die having a first surface and an opposing second surface;
wherein the first surface of the power semiconductor die is directly coupled to the first carrier substrate;
wherein the second surface of the power semiconductor die is directly coupled to the second carrier substrate.

2. The power semiconductor package of claim 1, wherein the power semiconductor die comprises a first contact on the first surface and a second contact on the second surface, wherein the first contact is directly coupled to at least one of the one or more conductive pads of the first carrier substrate, wherein the second contact is directly coupled to the second carrier substrate.

3. (canceled)

4. The power semiconductor package of claim 23, wherein the power semiconductor die comprises a third contact on the first surface, wherein the one or more conductive pads of the first carrier substrate comprises a first conductive pad and a second conductive pad, wherein the first contact is directly coupled to the first conductive pad and the third contact is directly coupled to the second conductive pad.

5. (canceled)

6. The power semiconductor package of claim 1, wherein the first carrier substrate is coupled to one or more second conductive leads of the power semiconductor package.

7. The power semiconductor package of claim 1, wherein the power semiconductor die is directly coupled to the first carrier substrate in a flip chip configuration.

8. The power semiconductor package of claim 1, wherein the first carrier substrate comprises a direct bonded copper (DBC) substrate or an active metal brazed (AMB) substrate.

9. The power semiconductor package of claim 1, wherein the second carrier substrate comprises a lead frame for the power semiconductor package.

10. The power semiconductor package of claim 1, wherein the first carrier substrate comprises a first surface and an opposing second surface, wherein the one or more conductive pads are on the first surface of the first carrier substrate, wherein the first carrier substrate comprises a thermally conductive cooling layer on the second surface.

11. The power semiconductor package of claim 10, wherein the thermally conductive cooling layer is exposed through an encapsulating portion of the power semiconductor package.

12. The power semiconductor package of claim 10, wherein the thermally conductive cooling layer is covered by an encapsulating portion of the power semiconductor package.

13. The power semiconductor package of claim 1, further comprising an insulating layer on the first contact of the power semiconductor die, wherein the insulating layer comprises a first dielectric material.

14. (canceled)

15. The power semiconductor package of claim 13, further comprising an encapsulating portion, the encapsulating portion comprising a second dielectric material.

16. The power semiconductor package of claim 15, wherein the first dielectric material is different from the second dielectric material such that the first dielectric material has a first dielectric constant, and the second dielectric material has a second dielectric constant, the first dielectric constant being different from the second dielectric constant.

17. (canceled)

18. The power semiconductor package of claim 15, wherein the first dielectric material is the same as the second dielectric material.

19. (canceled)

20. The power semiconductor package of claim 1, wherein the power semiconductor die comprises a wide band gap semiconductor.

21. The power semiconductor package of claim 20, wherein the wide band gap semiconductor is silicon carbide.

22. The power semiconductor package of claim 1, wherein the power semiconductor package does not include any wire bonds to the power semiconductor die.

23. The power semiconductor package of claim 1, wherein the power semiconductor die comprises a silicon carbide-based MOSFET.

24. The power semiconductor package of claim 1, wherein the power semiconductor die comprises a silicon carbide-based Schottky diode.

25.-41. (canceled)

42. A method of fabricating a power semiconductor package, the method comprising:
directly coupling a power semiconductor die to a first carrier substrate to form a first assembly;
directly coupling the first assembly to a second carrier substrate, the second carrier substrate comprising one or more conductive leads; and
encapsulating at least a portion of the first carrier substrate, the second carrier substrate, and the power semiconductor die to form an encapsulating portion.

43.-58. (canceled)
